(19) United States
(12) Patent Application Publication
(10) Pub. No.: US 2025/0169032 A1
(43) Pub. Date: May 22, 2025

(54) OPTICAL MODULE COOLING APPARATUS, OPTICAL MODULE SYSTEM, AND OPTICAL COMMUNICATION APPARATUS

(71) Applicant: SUZHOU METABRAIN INTELLIGENT TECHNOLOGY CO., LTD., Suzhou (CN)

(72) Inventors: Tao WANG, Suzhou (CN); Zhibo LYU, Suzhou, Jiangsu (CN); Xiaofeng MA, Suzhou, Jiangsu (CN)

(21) Appl. No.: 19/034,359

(22) Filed: Jan. 22, 2025

Related U.S. Application Data
(63) Continuation of application No. PCT/CN2023/134836, filed on Nov. 28, 2023.

(30) Foreign Application Priority Data
Feb. 8, 2023 (CN) 202310084934.7

(51) Int. Cl. H05K 7/20; G02B 6/42

(52) U.S. Cl. CPC H05K 7/20254; G02B 6/4269; H05K 7/20272; H05K 7/20281; H05K 7/2039

(57) ABSTRACT

An optical-module cooling device, an optical-module system and an optical-communication device. The optical-module cooling device includes a circulating mechanism and a plurality of cooling modules, the plurality of cooling modules are for being stacked with a plurality of layers of optical modules, and the plurality of cooling modules are connected in parallel. At least one of the cooling modules includes a plurality of cooling units, at least one of the cooling units is for contacting at least one of the optical modules to cool the at least one of the optical modules, and the plurality of cooling units are connected in parallel. The circulating mechanism is connected to the cooling modules, and the circulating mechanism is for driving a cooling medium to flow in parallel inside the plurality of cooling modules, and driving the cooling medium to flow in parallel inside the plurality of cooling units.

### CROSS-REFERENCE TO RELATED APPLICATION

The present application claims the priority of the Chinese patent application filed on Feb. 8, 2023 before the Chinese Patent Office with the application number of 202310084934.7 and the title of “OPTICAL MODULE COOLING APPARATUS, OPTICAL MODULE SYSTEM, AND OPTICAL COMMUNICATION APPARATUS”, which is incorporated herein in its entirety by reference.

### FIELD

The present application relates to the technical field of cooling devices, and particularly relates to an optical-module cooling device, an optical-module system and an optical-communication device.

### BACKGROUND

Optical-communication devices mainly refer to communicate devices that transmit information by utilizing light waves. The function of the optical module in an optical-communication device that has an optical module is converting an electric signal into an optical signal at an emitting terminal, which is transmitted by an optical fiber, and converting the optical signal into an electric signal at a receiving terminal.

In order to enable more data to be transmitted more quickly, the transmission speed of the optical modules grows quickly, and the power consumption and the density of the optical modules increase, which generates a large heat. In the prior art, the plurality of optical modules of an optical-communication device have the problem of a high temperature difference, which affects the data transmission speed.

### SUMMARY

In view of the above, the present application provides an optical-module cooling device, to solve or partially solve the problem that, in the conventional optical-communication devices, the plurality of optical modules have a high temperature difference.

In order to achieve the above object, in the first aspect, some embodiments of the present application provide an optical-module cooling device, wherein the optical-module cooling device comprises a circulating mechanism and a plurality of cooling modules, the plurality of cooling modules are for being stacked with a plurality of layers of optical modules, and the plurality of cooling modules are connected in parallel;

at least one of the cooling modules comprises a plurality of cooling units, at least one of the cooling units is for contacting at least one of the optical modules to cool the at least one of the optical modules, and the plurality of cooling units are connected in parallel; and

the circulating mechanism is connected to the cooling modules, and the circulating mechanism is for driving a cooling medium to flow in parallel inside the plurality of cooling modules, and driving the cooling medium to flow in parallel inside the plurality of cooling units.

In some embodiments, at least one of the cooling units comprises cooling flow channels for flowing-through of the cooling medium.

In some embodiments, the cooling unit comprises a unit housing and at least one partition plate, and the at least one partition plate is provided inside the unit housing, and segments the unit housing into at least two instances of the cooling flow channels.

In some embodiments, the cooling unit comprises a unit housing and a plurality of flow guiding columns, the flow guiding columns are provided inside the unit housing, and at least one of the flow guiding columns is connected to two opposite side walls of the unit housing; and

the plurality of flow guiding columns are arranged in an array, and gaps between the plurality of flow guiding columns form the cooling flow channels.

In some embodiments, at least one of the cooling modules further comprises a liquid intake pipe and a liquid outtake pipe, and both of the liquid intake pipe and the liquid outtake pipe are connected to the circulating mechanism;

one end of the cooling units is connected to the liquid intake pipe, and the other end of the cooling units is connected to the liquid outtake pipe; and

the liquid intake pipe, the liquid outtake pipe and the cooling units are connected to be of a flat structure.

In some embodiments, the liquid intake pipe and the liquid outtake pipe are parallel.

In some embodiments, at least one of the cooling modules further comprises a quick-insertion adapter, and the cooling module is connected to the circulating mechanism by the quick-insertion adapter.

In some embodiments, at least one of the cooling modules further comprises a connector, and the optical modules are provided inside cavities of optical cages; and

one end of the connector is connected to the cooling module, and the other end of the connector is inserted between two neighboring instances of the optical cages, and is connected to two side walls that face each other of the two neighboring optical cages.

In some embodiments, the other end of the connector comprises expansion parts, both of the two side walls that face each other are provided with a depression, and the expansion parts are adapted for being inserted into the depressions.

In some embodiments, the connector comprises a first connector and a second connector, and the first connector and the second connector are symmetrically arranged; and

the first connector comprises a first expansion part, the second connector comprises a second expansion part, the first expansion part is inserted into one of the depressions of the two side walls that face each other, and the second expansion part is inserted into the other of the depressions of the two side walls that face each other.

In some embodiments, in a cross section that is perpendicular to the cooling module and perpendicular to the two side walls that face each other, both of the first expansion part and the second expansion part are of an arc shape or a tetragon.

In some embodiments, the first connector comprises a first connecting part, the second connector comprises a second connecting part, the first connecting part connects the first expansion part and the cooling module, and the second connecting part connects the second expansion part and the cooling module; and

in a cross section that is perpendicular to the cooling module and perpendicular to the two side walls that face each other,

each of the first connecting part and the second connecting part is of a straight-line-segment structure; or

each of the first connecting part and the second connecting part is formed by a vertical part, a horizontal part and a vertical part that are sequentially connected, the vertical part of the first connecting part that is connected to the first expansion part and the vertical part of the second connecting part that is connected to the second expansion part are closer to each other, and the vertical part of the first connecting part that is connected to the cooling module and the vertical part of the second connecting part that is connected to the cooling module are farther from each other.

In some embodiments, the connector is an elastic-material member.

In some embodiments, at least two instances of the optical cages in any one of the layers are defined as one group, and the connector is inserted into a gap between two neighboring instances of the groups of the optical cages and is connected to the optical cages.

In some embodiments, the optical-module cooling device further comprises a heat conducting pad, one face of the heat conducting pad is connected to side walls of optical cages, and the other face of the heat conducting pad is connected to surfaces of the cooling units.

In some embodiments, the heat conducting pad comprises a heat conducting housing and a heat conducting medium, and the heat conducting medium is filled inside the heat conducting housing.

In some embodiments, at least two instances of the cooling units are arranged separately between a liquid intake pipe and a liquid outtake pipe; and

a direction of flowing of the cooling medium inside the cooling units is a length direction of the optical modules.

In the second aspect, some embodiments of the present application further provide an optical-module system, wherein the optical-module system comprises optical modules, optical cages and an optical-module cooling device, wherein the optical-module cooling device comprises a circulating mechanism and a plurality of cooling modules, the plurality of cooling modules are for being stacked with a plurality of layers of the optical modules, and the plurality of cooling modules are connected in parallel;

at least one of the cooling modules comprises a plurality of cooling units, at least one of the cooling units is for contacting at least one of the optical modules to cool the at least one of the optical modules, and the plurality of cooling units are connected in parallel;

the circulating mechanism is connected to the cooling modules, and the circulating mechanism is for driving a cooling medium to flow in parallel inside the plurality of cooling modules, and driving the cooling medium to flow in parallel inside the plurality of cooling units; and

the optical modules are provided inside cavities of the optical cages, and side walls of the optical cages contact the cooling modules.

In some embodiments, the optical-module system further comprises a fixing plate, an upper surface of the fixing plate is fixedly connected to one layer of the optical cages, and a lower surface of the fixing plate is fixedly connected to another layer of the optical cages; and

surfaces of the optical cages that are opposite to the fixing plate contact the cooling modules.

In the third aspect, some embodiments of the present application further provide an optical-communication device having optical modules, wherein the optical-communication device comprises an optical-module system, wherein the optical-module system comprises optical modules, optical cages and an optical-module cooling device, wherein the optical-module cooling device comprises a circulating mechanism and a plurality of cooling modules, the plurality of cooling modules are for being stacked with a plurality of layers of the optical modules, and the plurality of cooling modules are connected in parallel;

at least one of the cooling modules comprises a plurality of cooling units, at least one of the cooling units is for contacting at least one of the optical modules to cool the at least one of the optical modules, and the plurality of cooling units are connected in parallel;

the circulating mechanism is connected to the cooling modules, and the circulating mechanism is for driving a cooling medium to flow in parallel inside the plurality of cooling modules, and driving the cooling medium to flow in parallel inside the plurality of cooling units; and

the optical modules are provided inside cavities of the optical cages, and side walls of the optical cages contact the cooling modules.

As compared with the prior art, the optical-module cooling device according to the present application has the following advantages:

In the optical-module cooling device according to the present application, the plurality of cooling modules are for being stacked with the plurality of layers of the optical modules, and the plurality of cooling modules are connected in parallel. In the height direction, the optical modules may have a plurality of layers, and the cooling modules, as corresponding to the optical modules, may be plural, wherein the quantity of the layers of the optical modules is not limited by the height. The stacking arrangement between the cooling modules and the optical modules, as compared with other arrangement modes, may reduce the height room of the optical modules, so as to realize a high-density arrangement. Each of the cooling modules comprises a plurality of cooling units, and the plurality of cooling units are connected in parallel. Each of the cooling units is used for at least one of the optical modules. When there are a plurality of cooling units, the quantity of the optical modules in one layer is not limited. In conclusion, the height room of the plurality of layers of the optical modules and the length of extension of one layer of the optical modules are not limited, whereby the optical-module cooling device may simultaneously cool the plurality of optical modules of an unlimited quantity. The optical-module cooling device, by concentrative cooling to the plurality of layers of the plurality of optical modules, realizes the cooling to the plurality of optical modules of a high heat-flux density, whereby the optical-module cooling device has a high efficiency of cooling.

The plurality of cooling modules are connected in parallel, the plurality of cooling modules are independent of each other, and any one of the cooling modules does not influence the temperatures of the cooling mediums inside the other cooling modules. The plurality of cooling units are connected in parallel, the plurality of cooling units are independent of each other, and any one of the cooling units does not influence the temperatures of the cooling mediums inside the other cooling units. When the circulating mechanism is driving the cooling medium to flow in parallel inside the plurality of cooling modules, and driving the cooling medium to flow in parallel inside the plurality of cooling units, the temperatures of the cooling mediums inside the plurality of cooling modules and the temperatures of the cooling mediums inside the plurality of cooling units are equal. Therefore, after the cooling, the temperatures of the optical modules are equal, thermal agglomeration does not happen, and the optical modules have a high efficiency of data transmission.

The above description is merely a summary of the technical solutions of the present application. In order to more clearly know the elements of the present application to enable the implementation according to the contents of the description, and in order to make the above and other purposes, features and advantages of the present application more apparent and understandable, the particular embodiments of the present application will be provided below.

### BRIEF DESCRIPTION OF THE DRAWINGS

In order to more clearly illustrate the technical solutions of some embodiments of the present application, the figures that are required to describe some embodiments of the present application will be briefly described below. Apparently, the figures that are described below are embodiments of the present application, and a person skilled in the art can obtain other figures according to these figures without paying creative work.

FIG. 1 is a schematic structural diagram of an optical-module system according to some embodiments of the present application;

FIG. 2 is a schematic structural diagram of the interior of a cooling unit according to some embodiments of the present application;

FIG. 3 is a schematic structural diagram of a perspective view of the interior of a cooling unit according to some embodiments of the present application;

FIG. 4 is a schematic structural diagram of a connector according to some embodiments of the present application;

FIG. 5 is a schematic structural diagram of a connector according to some embodiments of the present application;

FIG. 6 is a schematic structural diagram of optical cages according to some embodiments of the present application;

FIG. 7 is a schematic structural diagram of the horizontal-extension arrangement of an optical-module system according to some embodiments of the present application;

FIG. 8 is a schematic structural diagram of the vertical-extension arrangement of an optical-module system according to some embodiments of the present application; and

FIG. 9 is a schematic structural diagram of the flowing directions of the cooling medium in an optical-module system according to some embodiments of the present application.

### DESCRIPTION OF THE REFERENCE NUMBERS

1—cooling modules; 11—liquid intake port; 12—liquid outtake port; 13—liquid intake pipe; 14—liquid outtake pipe; 15—cooling units; 151—cooling flow channels; 152—unit housing; 153—partition plate; 154—flow guiding columns; 16—liquid intake connecting tube; 17—liquid outtake connecting tube; 18—quick-insertion adapter; 19—connector; 191—first connector; 192—second connector; 201—first expansion part; 202—second expansion part; 21—heat conducting pad; 221—first connecting part; 222—second connecting part; 3—optical cages; 31—depressions; 4—optical modules; and 5—fixing plate.

### DETAILED DESCRIPTION

The technical solutions according to some embodiments will be clearly and completely described below with reference to the drawings. Apparently, the described embodiments are merely certain embodiments of the present application, rather than all of the embodiments. All of the other embodiments that a person skilled in the art obtains on the basis of the embodiments of the present application without paying creative work fall within the protection scope of the present application.

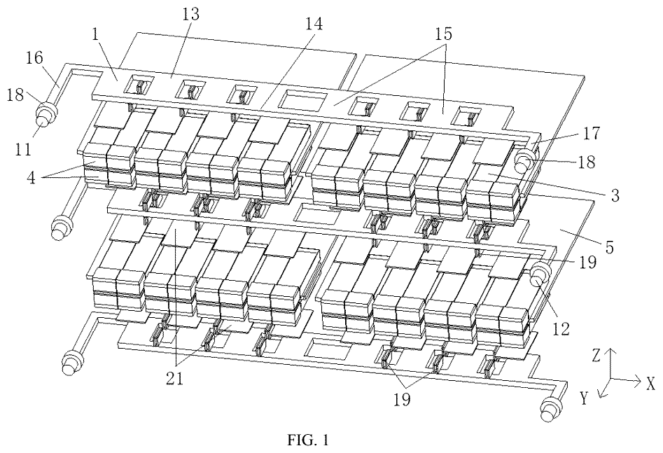

Some embodiments of the present application provide an optical-module cooling device. Referring to FIG. 1, FIG. 1 shows a schematic structural diagram of an optical-module cooling device according to some embodiments of the present application. The optical-module cooling device is used in an optical-module system, the optical-module system comprises optical cages 3 and optical modules 4, and the optical modules 4 are provided inside the cavities of the optical cages 3. The optical-module cooling device achieves the purpose of cooling the optical modules 4 by cooling the optical cages 3.

Referring to FIG. 1, the optical-module cooling device comprises a circulating mechanism and a plurality of cooling modules 1, the plurality of cooling modules 1 are for being stacked with a plurality of layers of optical modules 4, and the plurality of cooling modules 1 are connected in parallel. Each of the cooling modules 1 comprises a plurality of cooling units 15, each of the cooling units 15 is for contacting at least one of the optical modules 4 to cool the at least one of the optical modules 4, and the plurality of cooling units 15 are connected in parallel. The circulating mechanism is connected to the cooling modules 1, and the circulating mechanism is for driving a cooling medium to flow in parallel inside the plurality of cooling modules 1, and driving the cooling medium to flow in parallel inside the plurality of cooling units 15.

The optical module 4 is a connecting module serving for photovoltaic conversion. The optical module 4 may convert an electric signal into an optical signal by using an emitting terminal, which is transmitted by an optical fiber, and a receiving terminal converts the optical signal into an electric signal. In order to enable more data to be transmitted more quickly, the transmission speed of the optical module 4 grows quickly, which results in the increasing of the power density of the optical module 4. For example, the power consumption of a single 400 G optical module 4 reaches at most 15 W. Currently the data interaction between optical-communication devices is more efficient and frequent, wherein the optical-communication devices include, for example, servers and exchanges, and more high-power-consumption optical modules 4 are used, for example, 20, 40, 60, 100 or more optical modules 4. The increasing of the power density of the optical modules 4 causes that the operation process of the optical modules 4 generates a large amount of heat, in which case it is required to cool the optical modules 4, so as to prevent affecting the operation of the optical modules 4, for example, decreasing of the data transmission speed of the optical modules 4.

In some embodiments, the optical-module cooling device comprises a circulating mechanism and a plurality of cooling modules 1, and the circulating mechanism is used for cooling and circulating the cooling medium, to enable the cooling medium to be used repeatedly. It can be understood that the particular structure of the circulating mechanism is not limited in some embodiments of the present application, and it is merely required that the circulating mechanism satisfies the cooling and the circulation of the cooling medium. For example, the circulating mechanism is a cooling device that utilizes gas-liquid interaction or liquid-liquid interaction.

The cooling medium flows out of the circulating mechanism, and subsequently enters the cooling module 1 via a liquid intake port 11. The cooling medium inside the cooling module 1, after absorbing the heat transferred by the optical module 4 via the optical cage 3, has a temperature increase, and the cooling medium with the temperature increase flows back into the circulating mechanism via a liquid outtake port 12. After the circulating mechanism cools the cooling medium, the cooling medium repeats the above-described flowing path, so as to realize the continuous cooling to the optical module 4 by the cooling module 1.

The plurality of cooling modules 1 are for being stacked with the plurality of layers of the optical modules 4, wherein the plurality of cooling modules 1 refer to at least two cooling modules 1. The cooling modules 1 and the optical modules 4 may have single-face contacting, and may also have double-face contacting. For example, a cooling module 1 contacts the upper surface of one layer of the optical modules 4, or a cooling module 1 contacts the lower surface of one layer of the optical modules 4, or two cooling modules 1 contact the upper surface and the lower surface of one layer of the optical modules 4. It can be understood that the plurality of cooling modules 1 may be stacked with the plurality of layers of the optical modules 4 according to the usage demand. For example:

In some embodiments, referring to FIG. 1, the optical modules 4 have four layers, and three cooling modules 1 are provided. In the direction from top to bottom, the lower surface of the first cooling module 1 contacts the upper surface of the first layer of the optical modules 4, the upper surface of the second cooling module 1 contacts the lower surface of the second layer of the optical modules 4, the lower surface of the second cooling module 1 contacts the upper surface of the third layer of the optical modules 4, and the upper surface of the third cooling module 1 contacts the lower surface of the fourth layer of the optical modules 4. When the quantity of the layers of the optical modules 4 is continuously increased, the cooling modules 1 may be continuously provided in the above-described mode, so that the cooling modules 1 and the optical modules 4 contact to effectively cool the optical modules 4, whereby the optical modules 4 operate at a suitable temperature, so as to prevent decreasing of the data transmission speed of the optical modules 4.

In some embodiments, in the direction from top to bottom, the optical modules 4 have four layers, and four cooling modules 1 are provided. The lower surface of the first cooling module 1 contacts the upper surface of first layer of the optical modules 4, the upper surface of the second cooling module 1 contacts the lower surface of the second layer of the optical modules 4, the lower surface of the third cooling module 1 contacts the upper surface of the third layer of the optical modules 4, and the upper surface of the fourth cooling module 1 contacts the lower surface of the fourth layer of the optical modules 4. When the quantity of the layers of the optical modules 4 is continuously increased, the cooling modules 1 may be continuously provided in the above-described mode. In this case, because the cooling modules 1 and the layers of the optical modules 4 are provided correspondingly one to one, the temperature difference between the layers of the optical modules 4 may be reduced that is caused by that some of the cooling modules 1 cool one layer of the optical modules 4 and some of the cooling modules 1 cool two layers of the optical modules 4, and the temperatures of the layers of the optical modules 4 are more balanced, whereby the optical modules 4 operate at a suitable temperature, so as to prevent decreasing of the data transmission speed of the optical modules 4.

In some embodiments, in the direction from top to bottom, the optical modules 4 have four layers, and one cooling module 1 is provided. The first layer of the optical modules 4 and the fourth layer of the optical modules 4 do not contact the cooling module 1, and the cooling module 1 is provided between the second layer of the optical modules 4 and the third layer of the optical modules 4. The upper surface of the cooling module 1 contacts the lower surface of the second layer of the optical modules 4, and the lower surface of the cooling module 1 contacts the upper surface of the third layer of the optical modules 4. Because the first layer of the optical modules 4 and the fourth layer of the optical modules 4 are located on the upper and lower sides of the four layers of the optical modules 4, the first layer of the optical modules 4 and the fourth layer of the optical modules 4 may dissipate the heat. Therefore, as the first layer of the optical modules 4 and the fourth layer of the optical modules 4 operate at suitable temperatures, the upper side of the first layer of the optical modules 4 and the lower side of the fourth layer of the optical modules 4 may not be provided with the cooling modules 1, which reduces the cost of the optical-module cooling device, and may prevent decreasing of the data transmission speed caused by a high temperature of the optical modules 4.

In some embodiments, referring to FIG. 1, the cooling module 1 comprises a liquid intake pipe 13, a liquid outtake pipe 14 and cooling units 15, one end of the cooling units 15 is in communication with the liquid intake pipe 13, the other end of the cooling units 15 is in communication with the liquid outtake pipe 14, and the plurality of cooling units 15 are arranged in parallel and separately. The cooling medium flows out of the circulating mechanism, and subsequently enters the liquid intake pipe 13 via the liquid intake port 11. The cooling medium flows in the direction of extension of the liquid intake pipe 13. Referring to FIG. 1, the cooling medium flows in the direction X of the liquid intake pipe 13. The cooling medium inside the liquid intake pipe 13 enters the cooling unit 15 via one end of the cooling unit 15. The cooling units 15 contact the side walls of the optical cages 3. The cooling medium inside the cooling unit 15, after absorbing the heat transferred by the optical module 4 via the optical cage 3, has a temperature increase, and the cooling medium with the temperature increase flows out of the cooling unit 15 via the other end of the cooling unit 15 and subsequently enters the liquid outtake pipe 14. The cooling mediums with the temperature increase inside the plurality of cooling units 15 converge to the liquid outtake pipe 14, subsequently flow along the liquid outtake pipe 14, and subsequently flow out via liquid outtake port 12 to the circulating mechanism. After the circulating mechanism cools the cooling medium, the cooling medium repeats the above-described flowing path, so as to realize the continuous cooling to the optical modules 4.

It can be understood that the quantity of the cooling units 15 in the cooling module 1 is set according to the usage demand. In an embodiment of the present application, if one cooling module 1 has one cooling unit 15, one end of the cooling unit 15 is in communication with the liquid intake pipe 13, and the other end of the cooling unit 15 is in communication with the liquid outtake pipe 14. The one cooling unit 15 contacts the side wall of at least one of the optical modules 4. For example, the one cooling unit 15 contacts the side wall of one optical cage 3, or contacts the side walls of two optical cages 3, or contacts the side walls of three, five, and so on, optical cages 3, and the cooling unit 15 cools the optical modules 4 inside the optical cages 3 that contact the cooling unit 15.

In some embodiments, one cooling module 1 has a plurality of cooling units 15, wherein the plurality of cooling units 15 refer to at least two cooling units 15. In this case, in the direction of extension of the liquid intake pipe 13, i.e., the direction X in FIG. 1, the at least two cooling units 15 are arranged separately between the liquid intake pipe 13 and the liquid outtake pipe 14, one end of the cooling units 15 is in communication with the liquid intake pipe 13, and the other end of the cooling units 15 is in communication with the liquid outtake pipe 14. Each of the cooling units 15 contacts the side wall of at least one optical cage 3. For example, each of the cooling units 15 contacts the side wall of one optical cage 3, or contacts the side walls of two optical cages 3, or contacts the side walls of three, five, and so on, optical cages 3, and the cooling unit 15 cools the optical modules 4 inside the optical cages 3 that contact the cooling unit 15.

In the optical-module cooling device according to some embodiments of the present application, the plurality of cooling modules 1 are for being stacked with the plurality of layers of the optical modules 4, and the plurality of cooling modules 1 are connected in parallel. In the height direction, the optical modules 4 may have a plurality of layers, and the cooling modules 1, as corresponding to the optical modules 4, may be plural, wherein the quantity of the layers of the optical modules 4 is not limited by the height. The stacking arrangement between the cooling modules 1 and the optical modules 4, as compared with other arrangement modes, may reduce the height room of the optical modules 4, so as to realize a high-density arrangement. Each of the cooling modules 1 comprises a plurality of cooling units 15, and the plurality of cooling units 15 are connected in parallel. Each of the cooling units 15 is used for at least one of the optical modules 4. When there are a plurality of cooling units 15, the quantity of the optical modules 4 in one layer is not limited. In conclusion, the height room of the plurality of layers of the optical modules 4 and the length of extension of one layer of the optical modules 4 are not limited, whereby the optical-module cooling device may simultaneously cool the plurality of optical modules 4 of an unlimited quantity. The optical-module cooling device, by concentrative cooling to the plurality of layers of the plurality of optical modules 4, realizes the cooling to the plurality of optical modules 4 of a high heat-flux density, whereby the optical-module cooling device has a high efficiency of cooling. The plurality of cooling modules 1 are connected in parallel, the plurality of cooling modules 1 are independent of each other, and any one of the cooling modules 1 does not influence the temperatures of the cooling mediums inside the other cooling modules 1. The plurality of cooling units 15 are connected in parallel, the plurality of cooling units 15 are independent of each other, and any one of the cooling units 15 does not influence the temperatures of the cooling mediums inside the other cooling units 15. When the circulating mechanism is driving the cooling medium to flow in parallel inside the plurality of cooling modules 1, and driving the cooling medium to flow in parallel inside the plurality of cooling units 15, the temperatures of the cooling mediums inside the plurality of cooling modules 1 and the temperatures of the cooling mediums inside the plurality of cooling units 15 are equal. Therefore, after the cooling, the temperatures of the optical modules 4 are equal, thermal agglomeration does not happen, and the optical modules 4 have a high efficiency of data transmission.

It can be understood that, in practical applications, one layer of the cooling modules 1 may also be provided according to the usage demand, and the one layer of the cooling modules 1 may be stacked with at least one layer of the optical modules 4. For example, the one layer of the cooling modules 1 is stacked with one layer of the optical modules 4, or the one layer of the cooling modules 1 is provided between two layers of the optical modules 4, and is stacked with the two layers of the optical modules 4. In this case, the optical-module cooling device may realize the concentrative cooling to a single layer of one optical module, a single layer of a plurality of optical modules 4, and two layers of a plurality of optical modules 4.

In some embodiments, when the optical-module cooling device comprises at least one cooling module 1, it may realize the concentrative and high-efficiency cooling to a single layer of one optical module, a single layer of a plurality of optical modules 4, two layers of a plurality of optical modules 4, and a plurality of layers of a plurality of optical modules 4, without the aid by an air-cooling heat dissipating device in the heat dissipation of the optical modules 4. The optical-module cooling device may control the temperature difference of the plurality of optical modules 4 within 5°, which, as compared with the range of 10° of the temperature difference of the plurality of optical modules 4 when an air-cooling device is used for the heat dissipation of the optical modules 4, realizes the temperature equalization of the plurality of optical modules 4. Furthermore, the optical-module cooling device, as compared with an air-cooling heat sink for a single optical module 4, may reduce the overall volume of the optical modules 4, to save more room, to facilitate the assembling of other components and so on.

In some embodiments, the optical cages 3 employ a material of a high heat-transfer efficiency. For example, the optical cages 3 employ a metal material. The heat generated by the optical modules 4 is quickly transferred out via the optical cages 3, and subsequently the heat is transferred to the cooling units 15.

In some embodiments, each of the cooling units 15 comprises cooling flow channels 151 for the flowing-through of the cooling medium. The cooling flow channels 151 may enable the cooling medium inside cooling unit 15 to flow more evenly, whereby the cooling unit 15 cools the optical modules 4 inside the optical cages 3 better, and reduce the temperature difference of the plurality of optical modules 4, to realize the temperature equalization of the plurality of optical modules 4, whereby the plurality of optical modules 4 have a high data transmission speed.

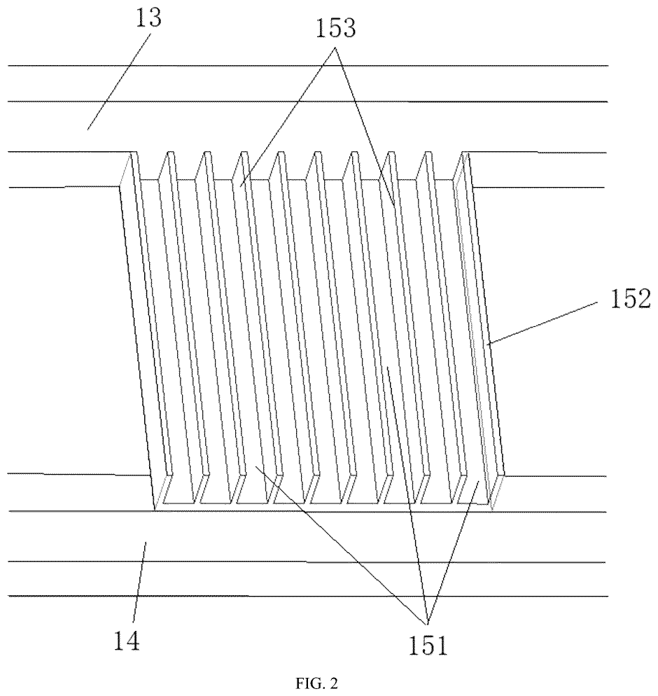

In some embodiments, referring to FIG. 2, FIG. 2 shows a schematic structural diagram of the interior of a cooling unit 15 according to some embodiments of the present application. The cooling unit 15 comprises a unit housing 152 and at least one partition plate 153, and the at least one partition plate 153 is provided inside the unit housing 152, and segments the unit housing 152 into at least two cooling flow channels 151. The unit housing 152 is of an elongate tubular structure. The opening at one end of the unit housing 152 is connected to the liquid intake pipe 13, the opening at the other end of the unit housing 152 is connected to the liquid outtake pipe 14, and the installation cavity enclosed by the unit housing 152 is in communication with the liquid intake pipe 13 and the liquid outtake pipe 14. The cooling medium inside the liquid intake pipe 13 enters the installation cavity via the one end of the unit housing 152, and subsequently the cooling medium enters the liquid outtake pipe 14 via the other end of the unit housing 152. The flowing process inside the installation cavity of the cooling medium is flowing in the cooling flow channels 151, whereby the cooling flow channels 151 may enable the cooling medium inside cooling unit 15 to flow more evenly, so as to reduce the temperature difference of the plurality of optical modules 4.

When the cooling unit 15 comprises one partition plate 153, the one partition plate 153 segments the interior of the unit housing 152 into two cooling flow channels 151, and the two cooling flow channels 151 are arranged in parallel. Further referring to FIG. 2, when the cooling unit 15 comprises a plurality of partition plates 153, the plurality of partition plates 153 are arranged parallelly and separately, and segment the interior of the unit housing 152 into a plurality of cooling flow channels 151 that are arranged in parallel. The cooling medium flows inside the cooling flow channels 151 evenly, which may enable the cooling medium to cool the optical modules 4 inside the optical cages 3 more evenly.

In some embodiments, the partition plate 153 is connected to the two opposite side walls of the unit housing 152. Referring to FIG. 2, the upper end of the partition plate 153 is connected to the upper side wall of the unit housing 152, and the lower end of the partition plate 153 is connected to the lower side wall of the unit housing 152. It can be understood that the mode of the connection between the partition plate 153 and the unit housing 152 may be selected according to the usage demand, and is not limited in the present application. For example, the partition plate 153 and the unit housing 152 are connected by welding, or the partition plate 153 and the unit housing 152 are integrally formed, or the partition plate 153 and the unit housing 152 are connected by plug connection, for example, by using a slot and a protrusion.

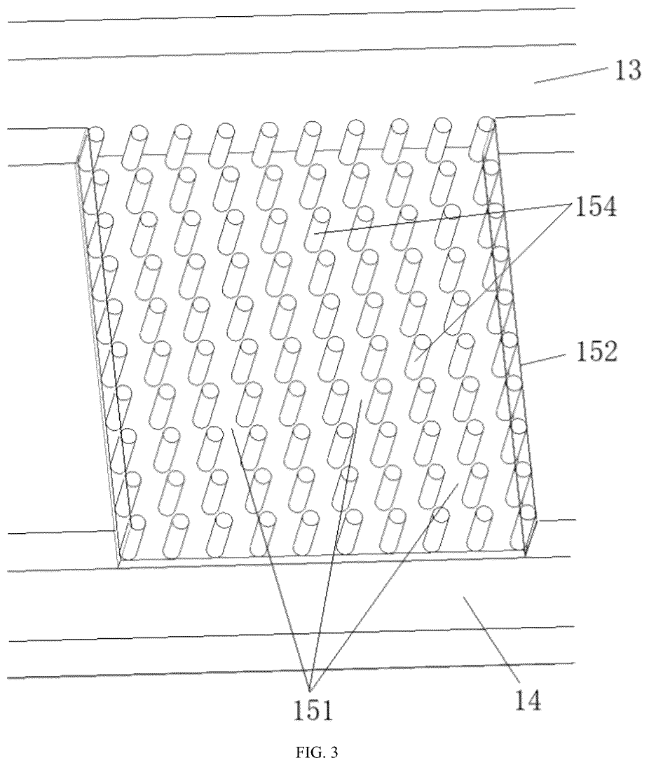

Referring to FIG. 3, FIG. 3 shows a schematic structural diagram of the interior of a cooling unit 15 according to some embodiments of the present application. The cooling unit 15 comprises a unit housing 152 and a plurality of flow guiding columns 154. The unit housing 152 is of an elongate tubular structure. The opening at one end of the unit housing 152 is connected to the liquid intake pipe 13, the opening at the other end of the unit housing 152 is connected to the liquid outtake pipe 14, and the installation cavity enclosed by the unit housing 152 is in communication with the liquid intake pipe 13 and the liquid outtake pipe 14. The flow guiding columns 154 are provided inside the unit housing 152, and each of the flow guiding columns 154 is connected to two opposite side walls of the unit housing 152. Referring to FIG. 3, the two ends of each of the flow guiding columns 154 are connected to the upper side wall and the lower side wall of the unit housing 152, the plurality of flow guiding columns 154 are arranged in an array, and the gaps between the plurality of flow guiding columns 154 form the cooling flow channels 151. The flowing process inside the installation cavity of the cooling medium is flowing in the cooling flow channels 151, whereby the cooling flow channels 151 may enable the cooling medium inside cooling unit 15 to flow more evenly, so as to reduce the temperature difference of the plurality of optical modules 4.

In some embodiments, referring to FIG. 3, the flow guiding column 154 is of a cylindrical structure, one end of the flow guiding column 154 is connected to the upper side wall of the unit housing 152, and the other end of the flow guiding column 154 is connected to the lower side wall of the unit housing 152. It can be understood that the particular shape of the flow guiding column 154 may be configured according to the usage demand, and is not limited in the present application. For example, the cross section of the flow guiding column 154 is of an elliptical shape. It can be understood that the mode of the connection between the flow guiding column 154 and the unit housing 152 may be selected according to the usage demand, and is not limited in the present application. For example, the flow guiding column 154 and the unit housing 152 are connected by welding, or the flow guiding column 154 and the unit housing 152 are integrally formed, or the flow guiding column 154 and the unit housing 152 are connected by plug connection, for example, by using a slot and a protrusion.

In some embodiments, referring to FIG. 1, each of the cooling modules 1 further comprises the liquid intake pipe 13 and the liquid outtake pipe 14, and both of the liquid intake pipe 13 and the liquid outtake pipe 14 are connected to the circulating mechanism. One end of the cooling units 15 is connected to the liquid intake pipe 13, and the other end of the cooling units 15 is connected to the liquid outtake pipe 14. In the direction X, the plurality of cooling units 15 are arranged in parallel and separately. The liquid intake pipe 13, the liquid outtake pipe 14 and the cooling units 15 are connected to be of a flat structure. The liquid intake pipe 13, the liquid outtake pipe 14 and the cooling unit 15 are the main parts that are stacked with the optical modules 4. When the liquid intake pipe 13, the liquid outtake pipe 14 and the cooling units 15 are connected to be of a flat structure, the distances between the liquid intake pipe 13, the liquid outtake pipe 14 and the cooling units 15 and any one of the layers of the optical modules 4 are more even, so as to ensure that the cooling module 1 and one layer of the optical modules 4 have the largest contact area therebetween, and the cooling units 15 may perform heat dissipation to the optical modules 4 inside the optical cages 3 better. Moreover, that may reduce the overall height when the plurality of cooling modules 1 and the at least one layer of the optical modules 4 are stacked, so as to save the room in the height direction.

In some embodiments of the present application, the liquid intake pipe 13 and the liquid outtake pipe 14 are parallel. In the direction from the liquid intake pipe 13 to the liquid outtake pipe 14, i.e., the direction Y in FIG. 1, the lengths of the cooling units 15 are equal, and the cooling units 15 may be configured as standard components. When the quantity of one layer of the optical modules 4 is configured according to the usage demand, the lengths of the liquid intake pipe 13 and the liquid outtake pipe 14 extend in the direction of arrangement of one layer of the optical modules 4. For example, as shown in FIG. 1, the plurality of optical modules 4 in one layer are arranged in the direction X, and the liquid intake pipe 13 and the liquid outtake pipe 14 are arranged in the direction X. By, according to the quantity of the optical modules 4 in one layer, providing the cooling units 15 of the corresponding quantity, the cooling modules 1 are suitable for the case in which in the layers there are optical modules 4 of different quantities.

In some embodiments, the liquid intake pipe 13, the liquid outtake pipe 14 and the cooling units 15 may be tubular components such as a copper pipe, an aluminum pipe and an alloy pipe, and after the tubular components have been crushed to a preset height, the liquid intake pipe 13, the liquid outtake pipe 14 and the cooling units 15 are connected. It can be understood that the mode of connecting the liquid intake pipe 13, the liquid outtake pipe 14 and the cooling units 15 is not limited in the present application. For example, the liquid intake pipe 13, the liquid outtake pipe 14 and the cooling units 15 are detachably connected by using sealing rings, or the liquid intake pipe 13, the liquid outtake pipe 14 and the cooling units 15 are seal-welded by using a welding process such as friction stir welding and braze welding, or the liquid intake pipe 13, the liquid outtake pipe 14 and the cooling units 15 are an integrally formed member.

In some embodiments, each of the liquid intake pipe 13, the liquid outtake pipe 14 and the cooling units 15 is at least one of a copper member, an aluminum member and an alloy member, all of the liquid intake pipe 13, the liquid outtake pipe 14 and the cooling units 15 have a good thermal conductivity, and the heat generated in the operation process of the optical modules 4 sequentially passes through the optical cages 3 and the unit housings 152 of the cooling units 15, and performs heat exchange with the cooling medium inside the cooling units 15, whereby the cooling units 15 realize the heat dissipation of the optical modules 4 inside the optical cages 3.

In some embodiments, referring to FIG. 1, each of the cooling modules 1 further comprises a liquid intake connecting tube 16 and a liquid outtake connecting tube 17, and the liquid intake connecting tube 16 and the liquid outtake connecting tube 17 are located on the two sides in the direction of extension of the liquid intake pipe 13, i.e., the two sides in the direction X. The liquid intake connecting tube 16 is used to connect the liquid intake port 11 and the liquid intake pipe 13, wherein one end of the liquid intake connecting tube 16 is the liquid intake port 11, and the other end of the liquid intake connecting tube 16 is connected to the liquid intake pipe 13. The liquid outtake connecting tube 17 is used to connect the liquid outtake port 12 and the liquid outtake pipe 14, wherein one end of the liquid outtake connecting tube 17 is the liquid outtake port 12, and the other end of the liquid outtake connecting tube 17 is connected to the liquid outtake pipe 14. Both of the liquid intake connecting tube 16 and the liquid outtake connecting tube 17 serve for connecting.

In some embodiments, both of the liquid intake connecting tube 16 and the liquid outtake connecting tube 17 are perpendicular to the direction of extension of the liquid intake pipe 13; in other words, both of the liquid intake connecting tube 16 and the liquid outtake connecting tube 17 shown in FIG. 1 are arranged in the direction Y. Both of one end of the liquid intake connecting tube 16 and one end of the liquid outtake connecting tube 17 are located on the outer sides of at least one layer of the optical modules 4, so as to facilitate the one end of the liquid intake connecting tube 16 to be connected to the circulating mechanism, and facilitate the one end of the liquid outtake connecting tube 17 to be connected to the circulating mechanism. In some embodiments, in the direction X, both of the liquid intake connecting tube 16 and the liquid outtake connecting tube 17 are on the outer sides of one layer of the optical modules 4, and the liquid intake connecting tube 16 and the liquid outtake connecting tube 17 do not affect the stacking of the cooling module 1 and the one layer of the optical modules 4.

It can be understood that the mode of connecting the liquid intake connecting tube 16 and the liquid intake pipe 13 and the mode of connecting the liquid outtake connecting tube 17 and the liquid outtake pipe 14 are configured according to the usage demand, and are not limited in the present application. For example, the liquid intake connecting tube 16 and the liquid intake pipe 13 are welded, or the liquid intake connecting tube 16 and the liquid intake pipe 13 are detachably connected by using a sealing member and so on, or the liquid intake connecting tube 16 and the liquid intake pipe 13 are an integrally formed pipe. For example, the liquid outtake connecting tube 17 and the liquid outtake pipe 14 are welded, or the liquid outtake connecting tube 17 and the liquid outtake pipe 14 are detachably connected by using a sealing member and so on, or the liquid outtake connecting tube 17 and the liquid outtake pipe 14 are an integrally formed pipe.

In some embodiments, each of the cooling modules 1 further comprises a quick-insertion adapter 18, and the cooling module 1 is connected to the circulating mechanism by the quick-insertion adapter 18. Referring to FIG. 1, particularly, each of one end of the liquid intake connecting tube 16 and one end of the liquid outtake connecting tube 17 is connected to a quick-insertion adapter 18, and the quick-insertion adapters 18 are connected to the circulating mechanism.

The quick-insertion adapter 18 is the most convenient plug-and-play connecting mode, and may realize the quick installation and detaching of the liquid intake connecting tube 16 and the liquid outtake connecting tube 17 to and from the interfaces on the circulating mechanism in a short time. Moreover, it may reduce the labour intensity of the operator. The operator is merely required to hold and rotate the handle of the quick-insertion adapter 18 to complete the operation of butting. In the pipe detaching, it is merely required to slightly rotate the handle in the opposite direction, and the liquid intake connecting tube 16 and the liquid outtake connecting tube 17 may be disengaged from the interfaces on the circulating mechanism. Furthermore, when the liquid intake connecting tube 16 and the liquid outtake connecting tube 17 are connected to the interfaces on the circulating mechanism by the quick-insertion adapters 18, they do not fall automatically, which prevents leakage of the cooling medium, thereby saving the cooling medium.

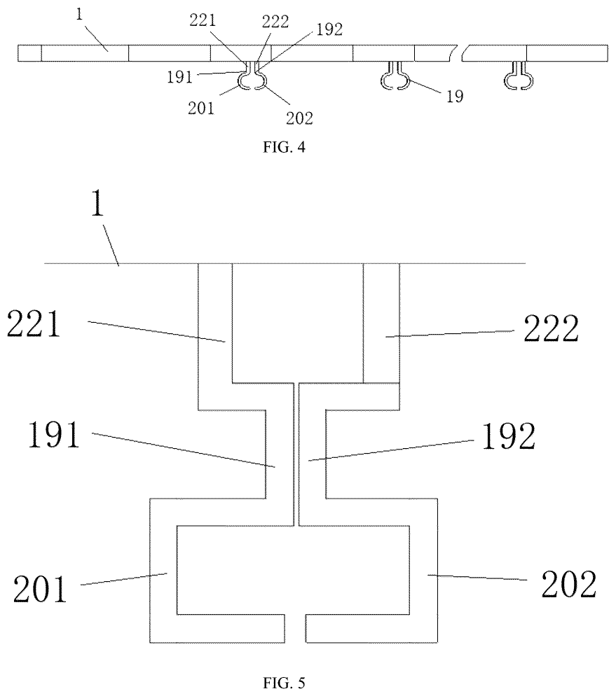

Each of the cooling modules 1 further comprises a connector 19. Referring to FIG. 4, FIG. 4 shows a schematic structural diagram of a connector 19 according to some embodiments of the present application. One end of the connector 19 is connected to the cooling module 1; for example, one end of the connector 19 is connected to the liquid intake pipe 13 and/or the liquid outtake pipe 14. The other end of the connector 19 is inserted between two neighboring optical cages 3, and is connected to two side walls that face each other of the two neighboring optical cages 3, so as to realize the fixed connection of the cooling module 1 and one layer of the optical modules 4.

Referring to FIG. 1, when the plurality of cooling modules 1 are for being stacked with the plurality of layers of the optical modules 4, the cooling modules 1 and the optical modules 4 may have single-face contacting, and may also have double-face contacting, and the connector 19 may be connected to one face of a cooling module 1, and may also be connected to two faces of a cooling module 1. For example:

In an embodiment of the present application, referring to FIG. 1, in the direction from top to bottom, the optical modules 4 have four layers, and three cooling modules 1 are provided. The lower surface of the first cooling module 1 is provided with the connector 19, the other end of the connector 19 is inserted between two neighboring optical cages 3 of the first layer of the optical modules 4, and is connected to two side walls that face each other of the two neighboring optical cages 3, and the lower surface of the first cooling module 1 contacts the upper surface of the first layer of the optical cages 3. Both of the upper surface and the lower surface of the second cooling module 1 are provided with the connector 19, the other end of the connector 19 connected to the upper surface of the second cooling module 1 is inserted between two neighboring optical cages 3 of the second layer of the optical modules 4, and is connected to two side walls that face each other of the two neighboring optical cages 3, and the upper surface of the second cooling module 1 contacts the lower surface of the second layer of the optical cages 3. The other end of the connector 19 connected to the lower surface of the second cooling module 1 is inserted between two neighboring optical cages 3 of the third layer of the optical modules 4, and is connected to two side walls that face each other of the two neighboring optical cages 3, and the lower surface of the second cooling module 1 contacts the upper surface of the third layer of the optical cages 3. The upper surface of the third cooling module 1 is provided with the connector 19, the other end of the connector 19 is inserted between two neighboring optical cages 3 of the fourth layer of the optical modules 4, and is connected to two side walls that face each other of the two neighboring optical cages 3, and the upper surface of the third cooling module 1 contacts the lower surface of the fourth layer of the optical cages 3.

In another embodiment of the present application, in the direction from top to bottom, the optical modules 4 have four layers, and four cooling modules 1 are provided. The lower surface of the first cooling module 1 is provided with the connector 19, the other end of the connector 19 is inserted between two neighboring optical cages 3 of the first layer of the optical modules 4, and is connected to two side walls that face each other of the two neighboring optical cages 3, and the lower surface of the first cooling module 1 contacts the upper surface of the first layer of the optical cages 3. The upper surface of the second cooling module 1 is provided with the connector 19, the other end of the connector 19 is inserted between two neighboring optical cages 3 of the second layer of the optical modules 4, and is connected to two side walls that face each other of the two neighboring optical cages 3, and the upper surface of the second cooling module 1 contacts the lower surface of the second layer of the optical cages 3. The lower surface of the third cooling module 1 is provided with the connector 19, the other end of the connector 19 is inserted between two neighboring optical cages 3 of the third layer of the optical modules 4, and is connected to two side walls that face each other of the two neighboring optical cages 3, and the lower surface of the third cooling module 1 contacts the upper surface of the third layer of the optical cages 3. The upper surface of the fourth cooling module 1 is provided with the connector 19, the other end of the connector 19 is inserted between two neighboring optical cages 3 of the fourth layer of the optical modules 4, and is connected to two side walls that face each other of the two neighboring optical cages 3, and the upper surface of the fourth cooling module 1 contacts the lower surface of the fourth layer of the optical cages 3.

In some embodiments, the mode of connecting the other end of the connector 19 and the two side walls that face each other of the two neighboring optical cages 3 may be configured according to the usage demand. For example:

In some embodiments, the connector 19 and the optical cages 3 are welded. The connecting mode of welding is firm and reliable. The mode of welding between the connector 19 and the optical cages 3 is selected according to the usage demand and the characteristics of the materials of the connector 19 and the optical cages 3. For example, the connector 19 and the optical cages 3 are welded by thermofussion welding, or the connector 19 and the optical cages 3 are welded by braze welding.

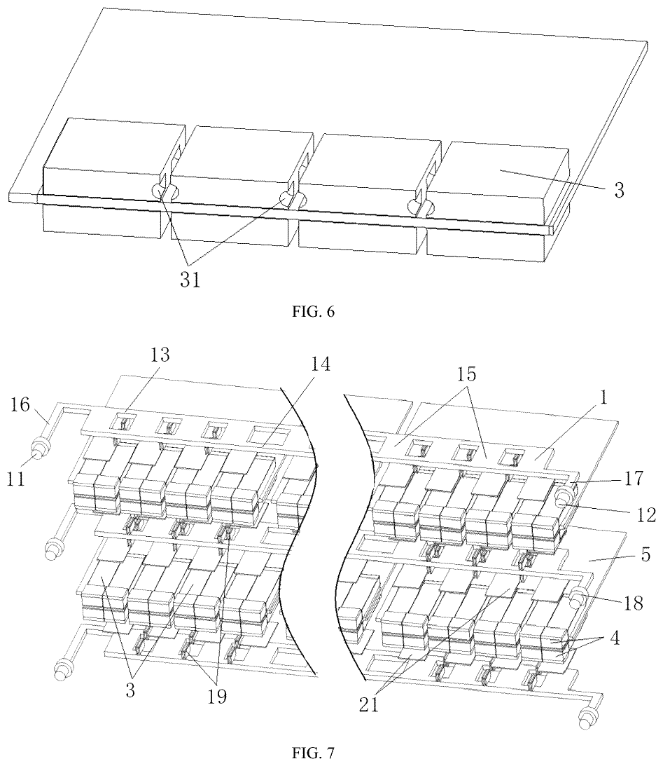

Referring to FIG. 4, the other end of the connector 19 comprises expansion parts. Further referring to FIG. 6, FIG. 6 shows a schematic structural diagram of optical cages 3 according to some embodiments of the present application. Both of the two side walls that face each other of two neighboring optical cages 3 are provided with a depression 31, and the expansion parts are adapted for being inserted into the depressions 31. In this case, when the cooling module 1 is being connected to one layer of the optical modules 4, the process may comprise directly aligning the connector 19 with the gap between the two neighboring optical cages 3 that are to be inserted between, pushing the other end of the connector 19 into the gap between the two neighboring optical cages 3, and stopping after the expansion parts have been inserted into the depressions 31, and, after they have been sequentially inserted, the connecting of the cooling module 1 to the one layer of the optical cages 3 is completed. Such a connecting mode does not require an assisting installing tool, and the installation is simple and convenient, and saves the installation cost.

In some embodiments, referring to FIG. 4, the connector 19 comprises a first connector 191 and a second connector 192, and the first connector 191 and the second connector 192 are symmetrically arranged. The first connector 191 comprises a first expansion part 201, the second connector 192 comprises a second expansion part 202, the first expansion part 201 and the second expansion part 202 are symmetrically arranged, the first expansion part 201 is inserted into one of the depressions 31 of the two side walls that face each other, and the second expansion part 202 is inserted into the other of the depressions 31 of the two side walls that face each other. For example, as shown in FIGS. 4 and 6, the first expansion part 201 is inserted into the left depression 31 of the two side walls that face each other, and the second expansion part 202 is inserted into the right depression 31 of the two side walls that face each other.

It can be understood that the shapes of the first expansion part 201 and the second expansion part 202 are configured according to the usage demand, and are not limited in the present application. The depressions 31 are required to match with the shapes of the first expansion part 201 and the second expansion part 202. For example, referring to FIG. 4, in a cross section that is perpendicular to the cooling module 1 and perpendicular to the two side walls that face each other, wherein, referring to FIG. 1, the cross section is the cross section XZ in FIG. 1, both of the first expansion part 201 and the second expansion part 202 are of an arc shape, and the first expansion part 201 and the second expansion part 202 are overall circular or elliptical. Further referring to FIG. 6, the depressions 31 are arc-shaped slots. As another example, referring to FIG. 5, in a cross section that is perpendicular to the cooling module 1 and perpendicular to the two side walls that face each other, both of the first expansion part 201 and the second expansion part 202 are of a tetragon, wherein the tetragon is, for example, a rectangle or a square, the first expansion part 201 and the second expansion part 202 are also overall a tetragon, and the depression 31 is a rectangular slot.

In some embodiments, the first connector 191 comprises a first connecting part 221, and the second connector 192 comprises a second connecting part 222. The first connecting part 221 connects the first expansion part 201 and the cooling module 1; for example, the first connecting part 221 is, particularly, connected to the liquid intake pipe 13 and/or the liquid outtake pipe 14. The second connecting part 222 connects the second expansion part 202 and the cooling module 1; for example, the second connecting part 222 is, particularly, connected to the liquid intake pipe 13 and/or the liquid outtake pipe 14. Both of the first connecting part 221 and the second connecting part 222 serve for connecting. In a cross section that is perpendicular to the cooling module 1 and perpendicular to the two side walls that face each other, referring to FIG. 1, the cross section is the cross section XZ in FIG. 1.

In some embodiments, referring to FIG. 4, each of the first connecting part 221 and the second connecting part 222 is of a straight-line-segment structure.

In some embodiments, the connector 19 is an elastic-material member. In this case, in the process of inserting the first connector 191 and the second connector 192 simultaneously between two neighboring optical cages 3, the first expansion part 201 and the second expansion part 202 are squeezed by the two side walls that face each other of the two neighboring optical cages 3 and deform and contract, the first expansion part 201 and the second expansion part 202 are correspondingly inserted into the two depressions 31 of the two side walls that face each other and subsequently stop, the first expansion part 201 and the second expansion part 202 expand, and both of the first expansion part 201 and the second expansion part 202 are clipped into the depressions 31.

In some other embodiments, referring to FIG. 5, in the direction from top to bottom, each of the first connecting part 221 and the second connecting part 222 is formed by a vertical part, a horizontal part and a vertical part that are sequentially connected, the vertical part of the first connecting part 221 that is connected to the first expansion part 201 and the vertical part of the second connecting part 222 that is connected to the second expansion part 202 are closer to each other, and the vertical part of the first connecting part 221 that is connected to the cooling module 1 and the vertical part of the second connecting part 222 that is connected to the cooling module 1 are farther from each other.

In some embodiments, the connector 19 is an elastic-material member. In this case, when each of the first connecting part 221 and the second connecting part 222 is formed by a vertical part, a horizontal part and a vertical part that are sequentially connected, in the process of inserting the first connector 191 and the second connector 192 simultaneously between two neighboring optical cages 3, the first expansion part 201 and the second expansion part 202 are squeezed by the two side walls that face each other of the two neighboring optical cages 3 and deform and contract, and, simultaneously, the vertical part of the first connecting part 221 that is connected to the first expansion part 201 and the vertical part of the second connecting part 222 that is connected to the second expansion part 202 squeeze each other. The first expansion part 201 and the second expansion part 202 are correspondingly inserted into the two depressions 31 of the two side walls that face each other and subsequently stop, the first expansion part 201 and the second expansion part 202 expand, and both of the first expansion part 201 and the second expansion part 202 are clipped into the depressions 31. simultaneously, the vertical part of the first connecting part 221 that is connected to the first expansion part 201 and the vertical part of the second connecting part 222 that is connected to the second expansion part 202 disengage from each other. Alternatively, the vertical part of the first connecting part 221 that is connected to the first expansion part 201 and the vertical part of the second connecting part 222 that is connected to the second expansion part 202 abut each other with a smaller squeezing force, and the vertical part of the first connecting part 221 that is connected to the first expansion part 201 and the vertical part of the second connecting part 222 that is connected to the second expansion part 202 abut each other to provide a separating force to the first expansion part 201 and the second expansion part 202, whereby both of the first expansion part 201 and the second expansion part 202 are stably clipped into the depressions 31.

In some embodiments, referring to FIG. 1, at least two optical cages 3 in any one of the layers are defined as one group, and the connector 19 is inserted into the gap between two neighboring groups of the optical cages 3 and is connected to the optical cages 3.

In some embodiments, referring to FIG. 1, the optical-module cooling device further comprises a heat conducting pad 21, one face of the heat conducting pad 21 is connected to side walls of optical cages 3, and the other face of the heat conducting pad 21 is connected to the surfaces of the cooling units 15. The heat conducting pad 21 is used for conducting the heat of the optical cages 3 to the cooling units 15, so that the cooling units 15 cool the optical modules 4 inside the optical cages 3 better.

In some embodiments, the heat conducting pad 21 comprises a heat conducting housing and a heat conducting medium, and the heat conducting medium is filled inside the heat conducting housing. If the heat conductivity coefficient of the heat conducting medium is higher, the effect of the heat conduction is better. When the cooling modules 1 are being installed, the heat conducting medium inside the heat conducting pad 21 may serve for cushioning to a certain extent, which may protect the cooling modules 1, thereby preventing the cooling modules 1 from being damaged, for example, knocked.

In some embodiments, the cooling medium is provided inside the circulating mechanism and the cooling modules 1, and the cooling medium comprises an aqueous solution of glycol, or a fluoridized liquid.

The coolant is formed by water, an antifreezing agent and an additive, may be classified into coolants of different types such as an alcohol type, a glycerin type and a glycol type according to the different compositions of the antifreezing agent, and is suitable to be used inside the circulating mechanism and the cooling modules 1.

The aqueous solution of glycol, as the secondary refrigerant, has the advantages of stable properties and a good thermodynamic property, and is also suitable to be used inside the circulating mechanism and the cooling modules 1.

The fluoridized liquid is a chemical solvent, is applied for liquid cooling for data centers and so on due to its inertial characteristics of being insulative and noncombustible, and is also suitable to be used inside the circulating mechanism and the cooling modules 1.

In some embodiments, the process of installing the optical-module cooling device comprises, referring to FIG. 1, matching one cooling module 1 with one layer of the optical modules 4, wherein the cooling module 1 is located over or under that layer of the optical modules 4, mounting the heat conducting pad 21, subsequently aligning one connector 19 on the cooling module 1 with the gap between two neighboring optical cages 3 of that to-be-inserted layer, subsequently pushing the other end of the connector 19 into the gap between the two neighboring optical cages 3, and stopping after the expansion parts have been inserted into the depressions 31; after all of the connectors 19 on the cooling module 1 have been connected to the optical cages 3, completing the connecting of the cooling module 1 to the one layer of the optical modules 4; repeating the above steps, till all of the cooling modules 1 have been connected to the corresponding plurality of layers of the optical modules 4; and subsequently, connecting the quick-insertion adapters 18 of the cooling modules 1 to the interfaces on the circulating mechanism, to complete the installation of the optical-module cooling device. The installation of the optical-module cooling device is a tool-free installation, and the installation is simple and convenient, and saves the installation cost. After the installation of the optical-module cooling device has been completed, the liquid intake connecting tubes 16 and the liquid outtake connecting tubes 17 are located on the two sides in the direction X of the plurality of layers of the optical modules 4, and the liquid intake ports 11 and the liquid outtake ports 12 are located on the outer sides in the direction Y of the plurality of layers of the optical modules 4.

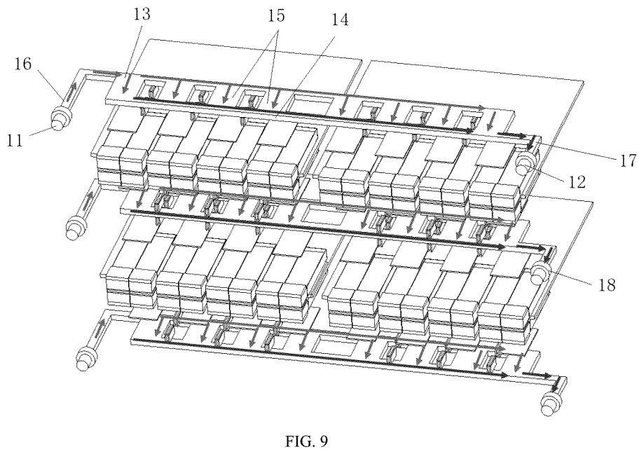

Referring to FIG. 9, FIG. 9 shows a schematic structural diagram of the flowing direction of the cooling medium in an optical-module cooling device according to some embodiments of the present application. The cooling medium flows out of the circulating mechanism, subsequently enters the liquid intake connecting tube 16 via the liquid intake port 11, and subsequently flows into the liquid intake pipe 13. Subsequently, while the cooling medium is flowing in parallel through the plurality of cooling units 15 that are connected in parallel, the cooling medium, after absorbing the heat transferred by the optical modules 4 via the optical cages 3, has a temperature increase. The cooling mediums with the temperature increase flow out of the cooling units 15, subsequently enter the liquid outtake pipe 14, converge inside the liquid outtake pipe 14, and subsequently, sequentially via the liquid outtake connecting tube 17 and the liquid outtake port 12, flow back into the circulating mechanism. During the flowing of the cooling medium in the optical-module cooling device, the cooling medium evenly enter the cavities of the cooling units 15, wherein the cooling medium that enters earlier exits later and the cooling medium that enters later exits earlier, so as to ensure that the temperatures of all of the cooling units 15 are equal, thereby ensuring that the temperatures of all of the optical modules 4 are balanced.

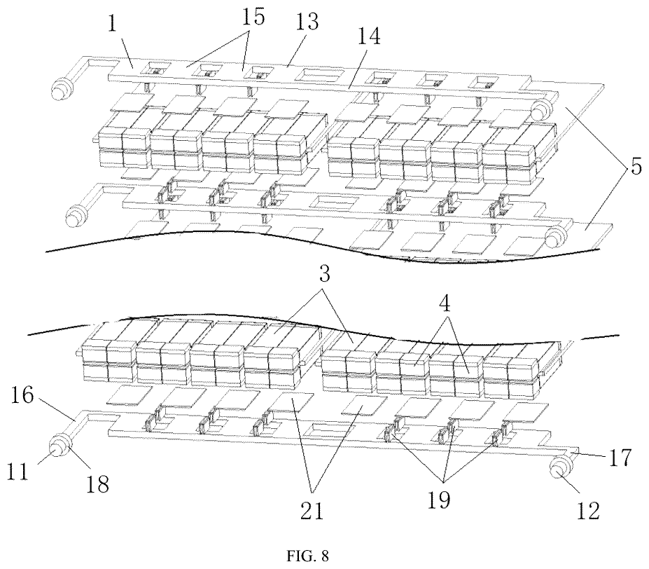

Referring to FIG. 7, FIG. 7 shows a schematic structural diagram of the horizontal-extension arrangement of optical modules 4 according to some embodiments of the present application. In one layer of the optical modules 4 a plurality of optical modules 4 may be provided. In the direction of extension of the liquid intake pipe 13, the optical modules 4 may extend without limitation, and, by changing the quantity of the cooling units 15, the cooling module 1 may satisfy the demand on extension in the horizontal direction of one layer of the optical modules 4. Referring to FIG. 8, FIG. 8 shows a schematic structural diagram of the vertical-extension arrangement of optical modules 4 according to some embodiments of the present application. In the height direction, the quantity of the layers of the optical modules 4 is not limited, and a plurality of layers of the optical modules 4 may be stacked without limitation. The optical-module cooling device realizes the concentrative cooling to a single layer of one optical module, a single layer of a plurality of optical modules 4, two layers of a plurality of optical modules 4, and a plurality of layers of a plurality of optical modules 4, and realizes the cooling to the plurality of optical modules 4 of a high heat-flux density, whereby the optical-module cooling device has a high efficiency of cooling. The plurality of cooling modules 1 are connected in parallel, and the plurality of cooling units 15 are connected in parallel. When the circulating mechanism drives the cooling medium to flow inside the cooling modules 1 and the cooling units 15, the temperatures of the cooling mediums inside the plurality of cooling modules 1 and the temperatures of the cooling mediums inside the plurality of cooling units 15 are equal. Therefore, after the cooling, the temperatures of the optical modules 4 are equal, thermal agglomeration does not happen, and the optical modules 4 have a high efficiency of data transmission.

The optical-module cooling device may be compatible with the optical modules 4 of a higher quantity, to support a higher capacity of data exchange inside the same volume, thereby increasing the space utilization ratio. The optical-module cooling device utilizes the repeatedly flowing cooling medium for the cooling, which, as compared with the heat dissipation using a fan, has the advantages of a smaller noise and a lower cost.

The cooling units 15 of the optical-module cooling device may be configured as standard components, so as to be applicable for the cooling of the optical modules 4 of different models.

The optical-module cooling device, in usage, may be connected in series to or connected in parallel to a cooling device for the CPU, a cooling device for the switching chip and a cooling device for the internal memory, and the circulating mechanism of the optical-module cooling device may be shared with the cooling device for the CPU, the cooling device for the switching chip and the cooling device for the internal memory, thereby realizing that the entire optical-module cooling device and the other cooling devices in the optical-communication device form a cooling system.

Some embodiments of the present application further provide an optical-module system. Referring to FIG. 1, the optical-module system comprises optical modules 4, optical cages 3 and the optical-module cooling device stated above. The optical modules 4 are provided inside the cavities of the optical cages 3, and the side walls of the optical cages 3 contact the cooling modules 1.

Because the optical-module cooling device realizes the concentrative cooling to a single layer of a plurality of optical modules 4, two layers of a plurality of optical modules 4, and a plurality of layers of a plurality of optical modules 4, and realizes the cooling to the plurality of optical modules 4 of a high heat-flux density, the optical-module system has the advantage of a high efficiency of cooling. The plurality of cooling modules 1 are connected in parallel, and the plurality of cooling units 15 are connected in parallel. The temperatures of the cooling mediums inside the plurality of cooling modules 1 and the temperatures of the cooling mediums inside the plurality of cooling units 15 are equal. Therefore, after the cooling, the temperatures of the optical modules 4 are equal, thermal agglomeration does not happen, and the optical modules 4 in the optical-module system have a high efficiency of data transmission.

In some embodiments, referring to FIG. 1, the optical-module system further comprises a fixing plate 5, the upper surface of the fixing plate 5 is fixedly connected to one layer of the optical cages 3, and the lower surface of the fixing plate 5 is fixedly connected to another layer of the optical cages 3. The surfaces of the optical cages 3 that are opposite to the fixing plate 5 contact the cooling modules 1. The fixing plate 5 serves for mounting and fixing the optical cages 3.

Some embodiments of the present application further provide an optical-communication device having an optical module, wherein the optical-communication device comprises the optical-module system stated above. The optical-communication device includes communicate devices that transmit information by utilizing light waves; for example, servers and exchanges commonly use an optical-module system. The optical-module system has the advantage of a good temperature-equalization performance. The optical modules 4 have a high data transmission speed, thereby improving the communication capacity of the optical-communication device.

It should be noted that, regarding the process embodiments, for brevity of the description, all of them are expressed as the combination of a series of actions, but a person skilled in the art should know that some embodiments of the present application are not limited by the sequences of the actions that are described, because, according to some embodiments of the present application, some of the steps may have other sequences or be executed simultaneously. Secondly, a person skilled in the art should also know that all of the embodiments described in the description are preferable embodiments, and not all of the actions that they involve are required by some embodiments of the present application.

It should be noted that the terms “include”, “comprise” or any variants thereof, as used herein, are intended to cover non-exclusive inclusions, so that processes, methods, articles or devices that include a series of elements do not only include those elements, but also include other elements that are not explicitly listed, or include the elements that are inherent to such processes, methods, articles or devices. Unless further limitation is set forth, an element defined by the wording “comprising a . . . ” does not exclude additional same element in the process, method, article or device comprising the element.

The embodiments of the present application are described above with reference to the drawings. However, the present application is not limited to the above particular embodiments. The above particular embodiments are merely illustrative, rather than limitative. A person skilled in the art, under the motivation of the present application, can make many variations without departing from the spirit of the present application and the protection scope of the claims, and all of the variations fall within the protection scope of the present application.

1. An optical-module cooling device, wherein the optical-module cooling device comprises a circulating mechanism and a plurality of cooling modules, the plurality of cooling modules are for being stacked with a plurality of layers of optical modules, and the plurality of cooling modules are connected in parallel;
at least one of the cooling modules comprises a plurality of cooling units, at least one of the cooling units is for contacting at least one of the optical modules to cool the at least one of the optical modules, and the plurality of cooling units are connected in parallel; and
the circulating mechanism is connected to the cooling modules, and the circulating mechanism is for driving a cooling medium to flow in parallel inside the plurality of cooling modules, and driving the cooling medium to flow in parallel inside the plurality of cooling units.

2. The optical-module cooling device according to claim 1, wherein at least one of the cooling units comprises cooling flow channels for flowing-through of the cooling medium.

3. The optical-module cooling device according to claim 2, wherein the cooling unit comprises a unit housing and at least one partition plate, and the at least one partition plate is provided inside the unit housing, and segments the unit housing into at least two instances of the cooling flow channels.

4. The optical-module cooling device according to claim 2, wherein the cooling unit comprises a unit housing and a plurality of flow guiding columns, the flow guiding columns are provided inside the unit housing, and at least one of the flow guiding columns is connected to two opposite side walls of the unit housing; and
the plurality of flow guiding columns are arranged in an array, and gaps between the plurality of flow guiding columns form the cooling flow channels.

5. The optical-module cooling device according to claim 1, wherein at least one of the cooling modules further comprises a liquid intake pipe and a liquid outtake pipe, and both of the liquid intake pipe and the liquid outtake pipe are connected to the circulating mechanism;
one end of the cooling units is connected to the liquid intake pipe, and the other end of the cooling units is connected to the liquid outtake pipe; and
the liquid intake pipe, the liquid outtake pipe and the cooling units are connected to be of a flat structure.

6. The optical-module cooling device according to claim 5, wherein the liquid intake pipe and the liquid outtake pipe are parallel.

7. The optical-module cooling device according to claim 1, wherein at least one of the cooling modules further comprises a quick-insertion adapter, and the cooling module is connected to the circulating mechanism by the quick-insertion adapter.

8. The optical-module cooling device according to claim 1, wherein at least one of the cooling modules further comprises a connector, and the optical modules are provided inside cavities of optical cages; and
one end of the connector is connected to the cooling module, and the other end of the connector is inserted between two neighboring instances of the optical cages, and is connected to two side walls that face each other of the two neighboring optical cages.

9. The optical-module cooling device according to claim 8, wherein the other end of the connector comprises expansion parts, both of the two side walls that face each other are provided with a depression, and the expansion parts are adapted for being inserted into the depressions.

10. The optical-module cooling device according to claim 9, wherein the connector comprises a first connector and a second connector, and the first connector and the second connector are symmetrically arranged; and
the first connector comprises a first expansion part, the second connector comprises a second expansion part, the first expansion part is inserted into one of the depressions of the two side walls that face each other, and the second expansion part is inserted into the other of the depressions of the two side walls that face each other.

11. The optical-module cooling device according to claim 10, wherein in a cross section that is perpendicular to the cooling module and perpendicular to the two side walls that face each other, both of the first expansion part and the second expansion part are of an arc shape or a tetragon.

12. The optical-module cooling device according to claim 10, wherein the first connector comprises a first connecting part, the second connector comprises a second connecting part, the first connecting part connects the first expansion part and the cooling module, and the second connecting part connects the second expansion part and the cooling module; and
in a cross section that is perpendicular to the cooling module and perpendicular to the two side walls that face each other,
each of the first connecting part and the second connecting part is of a straight-line-segment structure; or
each of the first connecting part and the second connecting part is formed by a vertical part, a horizontal part and a vertical part that are sequentially connected, the vertical part of the first connecting part that is connected to the first expansion part and the vertical part of the second connecting part that is connected to the second expansion part are closer to each other, and the vertical part of the first connecting part that is connected to the cooling module and the vertical part of the second connecting part that is connected to the cooling module are farther from each other.

13. The optical-module cooling device according to claim 8, wherein the connector is an elastic-material member.

14. The optical-module cooling device according to claim 8, wherein at least two instances of the optical cages in any one of the layers are defined as one group, and the connector is inserted into a gap between two neighboring instances of the groups of the optical cages and is connected to the optical cages.

15. The optical-module cooling device according to claim 1, wherein the optical-module cooling device further comprises a heat conducting pad, one face of the heat conducting pad is connected to side walls of optical cages, and the other face of the heat conducting pad is connected to surfaces of the cooling units.

16. The optical-module cooling device according to claim 15, wherein the heat conducting pad comprises a heat conducting housing and a heat conducting medium, and the heat conducting medium is filled inside the heat conducting housing.

17. The optical-module cooling device according to claim 1, wherein at least two instances of the cooling units are arranged separately between a liquid intake pipe and a liquid outtake pipe; and
a direction of flowing of the cooling medium inside the cooling units is a length direction of the optical modules.

18. An optical-module system, wherein the optical-module system comprises optical modules, optical cages and an optical-module cooling device, wherein the optical-module cooling device comprises a circulating mechanism and a plurality of cooling modules, the plurality of cooling modules are for being stacked with a plurality of layers of the optical modules, and the plurality of cooling modules are connected in parallel;
at least one of the cooling modules comprises a plurality of cooling units, at least one of the cooling units is for contacting at least one of the optical modules to cool the at least one of the optical modules, and the plurality of cooling units are connected in parallel;
the circulating mechanism is connected to the cooling modules, and the circulating mechanism is for driving a cooling medium to flow in parallel inside the plurality of cooling modules, and driving the cooling medium to flow in parallel inside the plurality of cooling units; and
the optical modules are provided inside cavities of the optical cages, and side walls of the optical cages contact the cooling modules.

19. The optical-module system according to claim 18, wherein the optical-module system further comprises a fixing plate, an upper surface of the fixing plate is fixedly connected to one layer of the optical cages, and a lower surface of the fixing plate is fixedly connected to another layer of the optical cages; and
surfaces of the optical cages that are opposite to the fixing plate contact the cooling modules.

20. An optical-communication device having optical modules, wherein the optical-communication device comprises an optical-module system, wherein the optical-module system comprises optical modules, optical cages and an optical-module cooling device, wherein the optical-module cooling device comprises a circulating mechanism and a plurality of cooling modules, the plurality of cooling modules are for being stacked with a plurality of layers of the optical modules, and the plurality of cooling modules are connected in parallel;
at least one of the cooling modules comprises a plurality of cooling units, at least one of the cooling units is for contacting at least one of the optical modules to cool the at least one of the optical modules, and the plurality of cooling units are connected in parallel;
the circulating mechanism is connected to the cooling modules, and the circulating mechanism is for driving a cooling medium to flow in parallel inside the plurality of cooling modules, and driving the cooling medium to flow in parallel inside the plurality of cooling units; and
the optical modules are provided inside cavities of the optical cages, and side walls of the optical cages contact the cooling modules.
